(19) United States
(12) Patent Application Publication
(10) Pub. No.: US 2026/0023120 A1
(43) Pub. Date: Jan. 22, 2026

(54) BATTERY MANAGEMENT APPARATUS AND METHOD

(71) Applicants: LG ENERGY SOLUTION, LTD., Seoul (KR); UNIVERSITY OF SOUTHERN CALIFORNIA, Los Angeles, CA (US)

(72) Inventors: Seonyoung JEGAL, Daejeon (KR); Mikyung Chung, Daejeon (KR); Dongwook Koh, Daejeon (KR); Min Jun Kim, Daejeon (KR); Seunghyun Kim, Daejeon (KR); Jay Hyung Lee, Los Angeles, CA (US); Jaewook Lee, Daejeon (KR)

(21) Appl. No.: 18/780,408

(22) Filed: Jul. 22, 2024

(51) Int. Cl. G01R 31/367; G01R 31/3842; G01R 31/392; G01R 31/396

(52) U.S. Cl. CPC G01R 31/367; G01R 31/3842; G01R 31/392; G01R 31/396

(57) ABSTRACT

According to an embodiment disclosed herein, a battery management apparatus includes a memory and a controller, in which the controller may be configured to obtain first charging/discharging data by performing a charging/discharging cycle on a first battery cell a first number of times, input input data comprising the first charging/discharging data to a two-dimensional (2D) convolutional neural network (CNN) trained based on second charging/discharging data obtained by performing the charging/discharging cycle on a second battery cell a second number of times, and predict a state of health (SOH) of the first battery cell, based on result data output through the 2D CNN in response to the input data.

### TECHNICAL FIELD

Embodiments disclosed herein relate to a battery management apparatus and method.

### BACKGROUND

As electric vehicles powered by electricity spread, research and development on new vehicle architectures are actively carried out. For example, the electric vehicles may be driven by secondary batteries which are chargeable/dischargeable batteries and include all of conventional nickel (Ni)/cadmium (Cd) batteries, Ni/metal hydride (MH) batteries, etc., and recent lithium-ion batteries. Among the secondary batteries, a lithium-ion battery has a much higher energy density than those of the conventional Ni/Cd batteries, Ni/MH batteries, etc. Moreover, the lithium-ion battery may be manufactured to be small and lightweight, such that the lithium-ion battery has been used as a power source of mobile devices, and recently, a use range thereof has been extended to power sources for electric vehicles, attracting attention as next-generation energy storage media.

The battery cell, the battery module, the battery pack, or the battery rack may be used in various devices. For example, the batteries may be used not only for mobile devices such as mobile phones, laptop computers, smart phones, smart pads, etc., but also in the field of vehicles (electric vehicles (EV), hybrid electric vehicles (HEV), plug-in HEV (PHEV)) driven with electricity, large-volume energy storage systems (ESS), etc.

These batteries may be managed and controlled in terms of states and operations thereof by a battery management system (BMS). The battery management system may be included together with a battery in one device.

Meanwhile, a battery cell may be charged and discharged based on various charging/discharging profiles. Through charging/discharging cycles for battery cells, a deterioration degree, a deterioration pattern, etc., of the battery cells over time may be identified. Based on an identification result, a replacement period, safety, etc., for a battery cell may be recognized, and a state of health (SOH) of another battery cell may be predicted based on the identified deterioration degree and deterioration pattern.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

By early predicting and analyzing a process in which a battery cell is deteriorated as the battery cell is charged and discharged, it is necessary to accurately identify a replacement period of the battery cell while securing safety of a device (e.g., an electric vehicle) using the battery cell.

Embodiments of the present disclosure aim to provide a battery management apparatus that accurately and efficiently predicts an SOH of a battery cell based on an analysis of charging/discharging data obtained from a relatively small number of charging/discharging cycles by a trained artificial intelligence model.

Technical problems of the embodiments disclosed herein are not limited to the above-described technical problems, and other unmentioned technical problems would be clearly understood by one of ordinary skill in the art from the following description.

According to an embodiment disclosed herein, a battery management apparatus includes a memory storing at least one instruction and a controller operatively connected to the memory. For example, the at least one instruction, when executed by the controller, may cause the battery management apparatus to obtain first charging/discharging data by performing a charging/discharging cycle on a first battery cell a first number of times, input the first charging/discharging data to a two-dimensional (2D) convolutional neural network (CNN) trained on second charging/discharging data obtained by performing the charging/discharging cycle on at least one second battery cell a second number of times, and predict a state of health (SOH) of the first battery cell based, at least in part, on result data output by the 2D CNN in response to the first charging/discharging data.

According to an embodiment, the first number of times may be less than the second number of times.

According to an embodiment, the first charging/discharging data may include one or more data sets including voltage data, current data, and temperature data corresponding to the first battery cell, and each of the one or more data sets corresponds to an instance of the charging/discharging cycle performed on the first battery cell.

According to an embodiment, the at least one instruction, when executed by the controller, may cause the battery management apparatus to identify a quantity of data sets included in the first charging/discharging data for a designated time period, determine that at least a portion of the first charging/discharging data is missing or incomplete in response to determining that the quantity of data sets is less than the first number of times, determine a target number of additional cycle iterations by calculating a difference between the quantity of data sets and the first number of times, and obtain third charging/discharging data by further performing the charging/discharging cycle for a number of iterations equal to the target number of additional cycle iterations.

According to an embodiment, the at least one instruction, when executed by the controller, may cause the battery management apparatus to input the third charging/discharging data to the 2D CNN, generate the result data output based, at least in part, on the third charging/discharging data, and predict the SOH of the first battery cell, based on the result data output in response to inputting the third charging/discharging data to the 2D CNN.

According to an embodiment, the target number of additional cycle iterations may be less than or equal to the first number of times.

According to an embodiment, the at least one instruction, when executed by the controller, may cause the battery management apparatus, to compare a prediction result generated by the 2D CNN based on the first charging/discharging data with an actual SOH of the first battery cell, identify error data based on said comparison of the prediction result and the actual SOH, the error data including at least one of a root mean squared error (RMSE), a mean absolute error (MAE), a standard deviation (STD), or any combination thereof. The controller may further utilize the error data to perform at least one of: update a target number of times the charging/discharging cycle is executed to generate a SOH prediction; or further train the 2D CNN using the error data.

According to an embodiment disclosed herein, a battery management method includes obtaining, by a controller, first charging/discharging data by performing a charging/discharging cycle on a first battery cell a first number of times, inputting, by the controller, the first charging/discharging data to a two-dimensional (2D) convolutional neural network (CNN) trained on second charging/discharging data obtained by performing the charging/discharging cycle on at one second battery cell a second number of times, and predicting, by the controller, a state of health (SOH) of the first battery cell based, at least in part, on result data output by the 2D CNN in response to the first charging/discharging data.

According to an embodiment, the battery management method may further include identifying, by the controller, a quantity of data sets included in the first charging/discharging data for a designated time period, determining, by the controller, that at least a portion of the first charging/discharging data is missing or incomplete in response to determining that the quantity of data sets is less than the first number of times, determining a target number of additional cycle iterations by calculating a difference between the quantity of data sets and the first number of times, and obtaining third charging/discharging data by further performing the charging/discharging cycle for a number of iterations equal to the target number of additional cycle iterations.

According to an embodiment, the battery management method may further include inputting the third charging/discharging data to the 2D CNN, generating the result data based, at least in part, on the third charging/discharging data, and predicting the SOH of the first battery cell based on the result data.

According to an embodiment, the battery management method may further include: comparing a prediction result generated by the 2D CNN based on the first charging/discharging data with an actual SOH of the first battery cell; identifying error data based on said comparison of the prediction result and the actual SOH, the error data comprising at least one of a root mean squared error (RMSE), a mean absolute error (MAE), a standard deviation (STD), or any combination thereof; and utilizing the error data to perform at least one of a) updating a target number of times the charging/discharging cycle is executed to make a SOH prediction, or b) further training the 2D CNN.

A battery management apparatus and method according to embodiments disclosed herein may provide an algorithm that stably and efficiently predicts an SOH of a battery merely with a small number of input data under various charging/discharging profiles.

Moreover, various effects recognized directly or indirectly from the disclosure may be provided.

### BRIEF DESCRIPTION OF DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawing.

FIG. 1 is a block diagram illustrating a structure of a battery management apparatus, according to an embodiment disclosed herein.

FIG. 2 is a block diagram illustrating a structure of a 2D CNN according to an embodiment disclosed herein.

FIG. 3A is a graph of result data output based on a specific charging/discharging cycle, according to an embodiment disclosed herein.

FIG. 3B is a graph of result data output based on a specific charging/discharging cycle, according to an embodiment disclosed herein.

FIG. 3C is a graph of result data output based on a specific charging/discharging cycle, according to an embodiment disclosed herein.

FIG. 3D is a graph of result data output based on a specific charging/discharging cycle, according to an embodiment disclosed herein.

FIG. 4 is a table of result data output based on a specific charging/discharging cycle, according to an embodiment disclosed herein.

FIG. 5 is a flowchart illustrating a battery management method according to an embodiment disclosed herein.

FIG. 6 is a block diagram showing a hardware configuration of a computing system for performing an operating method of a battery management apparatus, according to an embodiment disclosed herein.

### DETAILED DESCRIPTION

Hereinafter, various embodiments of the present disclosure will be disclosed with reference to the accompanying drawings. However, the description is not intended to limit the present disclosure to particular embodiments, and it should be construed as including various modifications, equivalents, and/or alternatives according to the embodiments of the present disclosure.

Herein, it is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. Such terms as “1^{st}” and “2^{nd},” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

Each component (e.g., a module or a program) of the components described herein may include a single entity or multiple entities. According to various embodiments, one or more of the components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

As used herein, the term “module” or “unit” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments of the present document may be implemented as software (e.g., a program or application) including one or more instructions that are stored in a storage medium (e.g., a memory) that is readable by a machine. For example, a processor of the machine may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Herein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

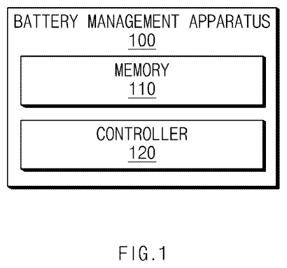

FIG. 1 is a block diagram illustrating a structure of a battery management apparatus, according to an embodiment disclosed herein.

Referring to FIG. 1, a battery management apparatus 100 may include a memory 110 and/or a controller 120.

According to an embodiment, the memory 110 may store a command or data. For example, the memory 110 may store one or more instructions that cause the battery management apparatus 100, when executed by the controller 120, to perform various operations.

For example, the memory 110 may be implemented as one chipset with the controller 120. The controller 120 may include at least one of a communication processor or modem.

For example, the memory 110 may store various information associated with the battery management apparatus 100. For example, the memory 110 may store information about an operation history of the controller 120. For example, the memory 110 may store information associated with states and/or operations of other components (e.g., at least one of a sensor unit, a display unit, an interface, a battery cell, or a combination thereof) of the battery management apparatus 100.

For example, the memory 110 may include a plurality of storage devices of different types. For example, the memory 110 may include at least one of a random-access memory (RAM), an embedded multi-media card (eMMC), or any combination of thereof.

According to an embodiment, the controller 120 may be operatively connected to the memory 120. For example, the controller 120 may control an operation of the memory 110.

For example, the controller 120 may obtain first charging/discharging data by performing the charging/discharging cycle on a first battery cell a first number of times.

For example, charging and discharging may be performed based on a charging/discharging profile designated for the first battery cell. The designated charging/discharging profile may include setting values, for example, a pressure size, an ambient temperature, a charging mode (e.g., quick charging, normal charging, slow charging) for the battery cell. A charging mode may be classified according to, for example, a charging pattern (e.g., quick charge (QC) or slow charge (SC)), voltage and/or current conditions for terminating charging, a rest period after charging, a discharging pattern, voltage and/or current conditions for terminating discharging, and a rest period after discharging.

For example, the controller 120 may charge and discharge the first battery cell a first number of times, based on a predefined charging/discharging profile. A process in which the battery cell is charged and discharged may be defined as one charging/discharging cycle.

For example, the controller 120 may input or provide input data including first charging/discharging data to a two-dimensional (2D) convolutional neural network (CNN).

For example, the 2D CNN may include an artificial intelligence model trained based on second charging/discharging data obtained by performing a charging/discharging cycle on a second battery cell a second number of times.

For example, the controller 120 may train the 2D CNN by using the second charging/discharging data obtained while performing the charging/discharging cycle on the second battery cell the second number of times (e.g., 270 times).

For example, the 2D CNN may include an input layer, a pooling layer, a non-pooling layer, a linear layer, and an output layer. The 2D CNN may include as many 2D CNN models as the pooling layer and the non-pooling layer.

For example, the controller 120 may fix the number of pooling layers to n (e.g., 1), and change the number of non-pooling layers to determine the number of times the charging/discharging cycle is performed such that an optimal prediction result may be derived.

For example, the controller 120 may predict an SOH of the first battery cell based on result data output through the 2D CNN in response to the input data.

For example, the first number of times may be less than the second number of times.

For example, the first charging/discharging data and/or the second charging/discharging data may include at least one data set regarding a voltage, a current, and a temperature of a battery cell corresponding to each time of the charging/discharging cycle. The first charging/discharging data may include a first number of (e.g., three to five) data sets corresponding to each time of the charging/discharging cycle performed the first number of times (e.g., three to ten times). The second charging/discharging data may include a second number of (e.g., 250 to 290) data sets corresponding to each time of the charging/discharging cycle performed the second number of times (e.g., 250 to 290 times).

For example, the controller 120 may monitor, based on a designated period, whether the number of data sets included in the first charging/discharging data is less than the first number. The controller 120 may determine that at least a part of the first charging/discharging profile is missed when the number of data sets included in the first charging/discharging data is less than the first number corresponding to the first number of times. In this case, the controller 120 may obtain third charging/discharging data by further performing the charging/discharging cycle on the first battery cell as many times as a target number of times corresponding to a difference between the first number and the number of data sets. The target number of times may be less than or equal to, for example, the first number of times.

For example, the controller 120 may predict the SOH of the first battery cell based on result data output by further inputting third charging/discharging data to the 2D CNN. That is, the controller 120 may input the first number of data sets to the 2D CNN by additionally performing the charging/discharging cycle when identifying that the number of data sets included in the first charging/discharging data is less than the first number corresponding to the first number of times.

For example, the controller 120 may update the first number of times (or the number of times of charging/discharging for SOH prediction) based on the accuracy of the SOH prediction result of the first battery cell.

For example, the controller 120 may compare a prediction result output by inputting the first charging/discharging data to the 2D CNN with an actual SOH of the first battery cell.

For example, the controller 120 may identify error data including at least one of a root mean squared error (RMSE), a mean absolute error (MAE), a standard deviation (STD), or any combination thereof, based on a result of comparison between the prediction result and the actual SOH.

For example, the controller 120 may update a target number of times of the charging/discharging cycle for SOH prediction by using the error data. The controller 120 may increase or reduce the target number of times of the charging/discharging, based on the error data. The target number of times of the charging/discharging cycle may be 3 times to 10 times, but this is merely an example and embodiments of the present disclosure are not limited thereto.

For example, the controller 120 may obtain charging/discharging data for SOH prediction by performing the charging/discharging cycle on the third battery cell as many times as the target number of times of the charging/discharging cycle after termination of SOH prediction on the first battery cell.

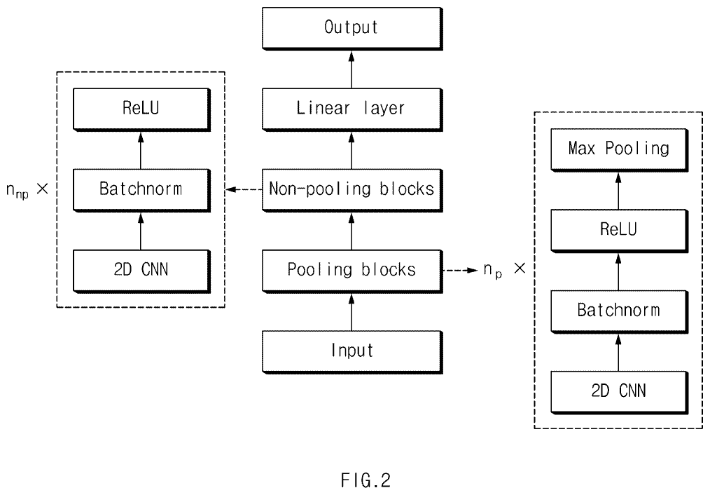

FIG. 2 is a block diagram illustrating a structure of a 2D CNN according to an embodiment disclosed herein.

According to an embodiment, the battery management apparatus (e.g., the battery management apparatus 100 of FIG. 1) may predict the SOH of the battery cell based on the 2D CNN of FIG. 2.

For example, the 2D CNN may include an input layer. The battery management apparatus may input at least one charging/discharging data to the input layer of the 2D CNN.

For example, the 2D CNN may include pooling blocks including at least one pooling layer.

For example, the battery management apparatus may process the input data through np pooling layers. The battery management apparatus may process the input data by fixing np to, for example, 1. The pooling layer may include, for example, a 2D CNN layer, a batch normalization layer Batchnorm, a rectified linear unit ReLu, and a max pooling layer.

For example, the 2D CNN may include non-pooling blocks including at least one non-pooling layer.

For example, the battery management apparatus may process data transmitted from the pooling blocks through nₙₚ non-pooling layers. The battery management apparatus may process data while adjusting nₙₚ within a designated range (e.g., three to ten) to derive an optimal result. The non-pooling layer may include, for example, a 2D CNN layer, a batch normalization layer Batchnorm, and a rectified linear unit ReLu.

For example, the 2D CNN may include a linear layer.

For example, the battery management apparatus may perform linear transformation on data transmitted from the non-pooling blocks through the linear layer.

For example, the 2D CNN may include an output layer.

For example, the battery management apparatus may predict the SOH of the battery cell through the result data output from the output layer.

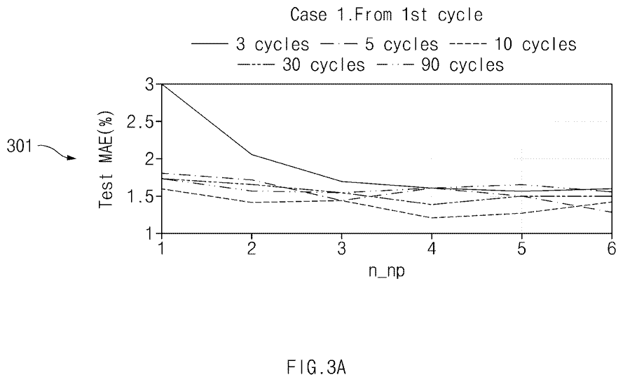

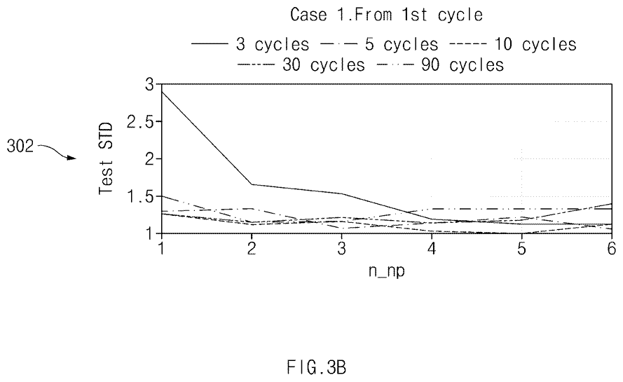

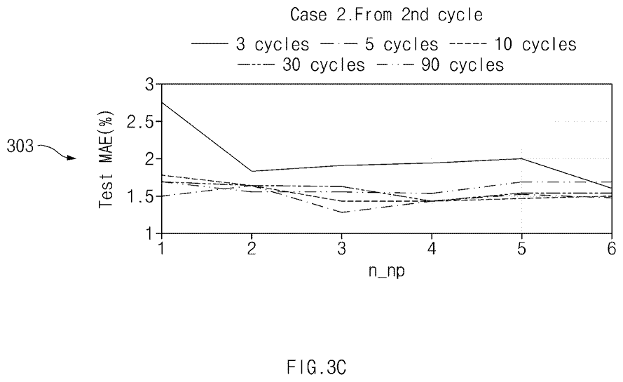

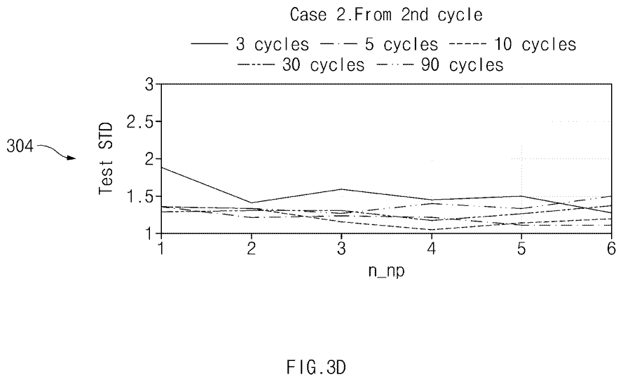

In the following description made with reference to FIGS. 3A to 3D, an MAE and an STD of a prediction result according to a type of the charging/discharging cycle, the number of times of the charging/discharging cycle, and the number of non-pooling layers will be described. For example, in a graph, an x axis indicates the number of non-pooling layers, nₙₚ, and a y axis indicates the MAE and the STD of the prediction result.

FIGS. 3A and 3B are graphs of result data output based on a specific charging/discharging cycle, according to an embodiment disclosed herein.

Reference numerals 301 and 302 indicate SOH prediction results predicted based on a plurality of charging/discharging data including charging/discharging data obtained through an initial charging/discharging cycle on a battery cell. That is, performance of an SOH prediction result predicted including charging/discharging data corresponding to a first charging/discharging cycle is shown.

For example, when nₙₚ is 1 and the charging/discharging cycle is performed three times, the MAE of the prediction result may be 3%.

For example, when nₙₚ is 2 and the charging/discharging cycle is performed three times, the MAE of the prediction result may be about 2%.

For example, when nₙₚ is 3 to 6 and the charging/discharging cycle is performed 3 to 90 times, the MAE of the prediction result may be less than 2%.

For example, when nₙₚ is 1 and the charging/discharging cycle is performed three times, the STD of the prediction result may be 3%.

For example, when nₙₚ is 2 and the charging/discharging cycle is performed three times, the STD of the prediction result may be about 1.7%.

For example, when nₙₚ is 3 to 6 and the charging/discharging cycle is performed 3 to 90 times, the STD of the prediction result may be less than 1.5%.

FIGS. 3C and 3D are graphs of result data output based on a specific charging/discharging cycle, according to an embodiment disclosed herein.

Reference numerals 303 and 304 indicate SOH prediction results predicted based on a plurality of charging/discharging data in which charging/discharging data obtained through an initial charging/discharging cycle on a battery cell is missed. That is, performance of an SOH prediction result in a situation where charging/discharging data corresponding to the first charging/discharging cycle is missed may be shown.

For example, when nₙₚ is 1 and the charging/discharging cycle is performed three times, the MAE of the prediction result may be about 2.8%.

For example, when nₙₚ is 2 and the charging/discharging cycle is performed three times, the MAE of the prediction result may be about 1.9%.

For example, when nₙₚ is 3 to 6 and the charging/discharging cycle is performed 3 to 90 times, the MAE of the prediction result may be less than 2%.

For example, when nₙₚ is 1 and the charging/discharging cycle is performed three times, the STD of the prediction result may be about 1.9%.

For example, when nₙₚ is 2 and the charging/discharging cycle is performed three times, the STD of the prediction result may be about 1.4%.

For example, when nₙₚ is 3 to 6 and the charging/discharging cycle is performed 3 to 90 times, the STD of the prediction result may be less than 1.6%.

For example, the battery management apparatus may identify that the MAE and the STD are low as a whole in spite of low nₙₚ when the number of times of the charging/discharging cycle is 5 times, 10 times, 30 times, or 90 times.

Thus, the battery management apparatus may identify that the MAE and the STD are low as a whole when nₙₚ is set to 3 to 6 in spite of a small number of times of the charging/discharging cycle, and use the 2D CNN within a corresponding range, thereby outputting the SOH prediction result having high accuracy through a relatively small number of times of the charging/discharging cycle.

Moreover, as there is no significant difference in accuracy of the prediction result even when charging/discharging data corresponding to a specific cycle (e.g., an initial cycle) is missed, the battery management apparatus may output the prediction result or output an SOH prediction result having robust accuracy by further using charging/discharging data corresponding to another cycle.

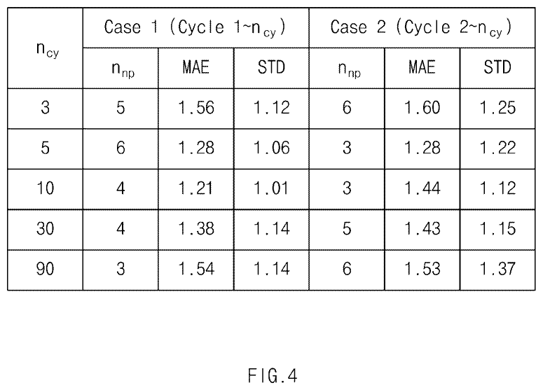

FIG. 4 is a table of result data output based on a specific charging/discharging cycle, according to an embodiment disclosed herein.

According to an embodiment, the battery management apparatus (e.g., the battery management apparatus 100 of FIG. 1) may identify the MAE and the STD of the prediction result while changing the number of times of the charging/discharging cycle, n_{cy}, and the number of non-pooling layers, nₙₚ. Moreover, the battery management apparatus may identify the MAE and the STD of the prediction result in a situation where the charging/discharging data corresponding to the specific cycle (e.g., the first cycle) is missed.

Referring to FIG. 4, a case where prediction is performed including charging/discharging data corresponding to a specific cycle may be defined as Case 1, and a case where prediction is performed missing the charging/discharging data corresponding to the specific cycle may be defined as Case 2.

For example, in Case 1, as the MAE and the STD are low when the number of times of charging/discharging, n_{cy}, is 5 to 10 times and the number of non-pooling layers, nₙₚ, is 4 or 6, such that the accuracy of the prediction result may be relatively high. The battery management apparatus may update a target number of times of the charging/discharging cycle or train the 2D CNN.

For example, in Case 2, as the MAE and the STD are low when the number of times of charging/discharging, n_{cy}, is 5 times and the number of non-pooling layers, nₙₚ, is 3, such that the accuracy of the prediction result may be relatively high. The battery management apparatus may update a target number of times of the charging/discharging cycle or train the 2D CNN.

According to results of Case 1 and Case 2, as the accuracy of a prediction result does not significantly change even when charging/discharging data corresponding to a specific cycle is missed, the prediction result may be output even when partial charging/discharging data is missed, or the SOH prediction result having robust accuracy may be output based on the charging/discharging data obtained by further performing the charging/discharging cycle.

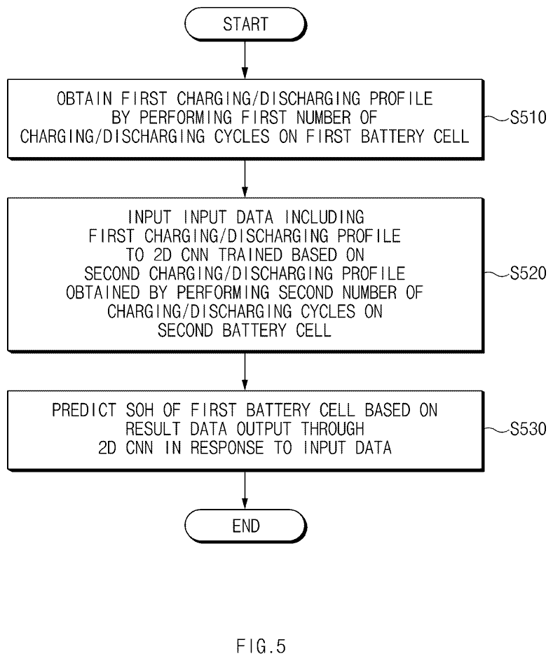

FIG. 5 is a flowchart illustrating a battery management method according to an embodiment disclosed herein.

According to an embodiment, the battery management apparatus (e.g., the battery management apparatus 100 of FIG. 1) may perform operations described with reference to FIG. 5. For example, at least some of components (e.g., the memory 110 and the controller 120 of FIG. 1) included in the battery management apparatus may be configured to perform operations of FIG. 5.

In the following embodiment, operations S510 to S530 may be performed sequentially, but may not be necessarily performed sequentially. For example, the order of operations may be changed and at least two operations may be performed in parallel. In relation to FIG. 5, matters corresponding to or redundant to the above-described matters may be briefly described or omitted.

Referring to FIG. 5, a battery management method may include operation S510 of obtaining a first charging/discharging profile by performing a charging/discharging cycle on a first battery cell a first number of times, operation S520 of inputting input data including the first charging/discharging profile to a 2D CNN trained based on a second charging/discharging profile obtained by performing the charging/discharging cycle on a second battery cell a second number of times, and operation S530 of predicting an SOH of the first battery cell based on result data output through the 2D CNN in response to the input data.

In operation S510, the battery management apparatus may charge and discharge the first battery cell the first number of times. For example, the battery management apparatus may control charging and discharging of the first battery cell based on the first number of times defined as a target number of times of the charging/discharging cycle. The first number of times may be 3 times to 10 times, but this is merely an example and embodiments of the present disclosure are not limited thereto.

In operation S520, the battery management apparatus may predict the SOH of the first battery cell by using the 2D CNN. For example, the 2D CNN may be an artificial intelligence model trained based on second charging/discharging data obtained by performing charging and discharging on the second battery cell the second number of times. The second number of times may be 250 times to 290 times, but this is merely an example and embodiments of the present disclosure are not limited thereto.

In operation S530, the battery management apparatus may predict the SOH of the first battery cell based on result data obtained through the 2D CNN. The battery management apparatus may identify error data including at least one of an RMSE, an MAE, an STD, or any combination thereof, based on a result of comparison between a prediction result and an actual SOH of the first battery cell, and train the 2D CNN or update the target number of times of the charging/discharging cycle, based on a size of the identified error data and whether the identified error data exceeds a threshold value.

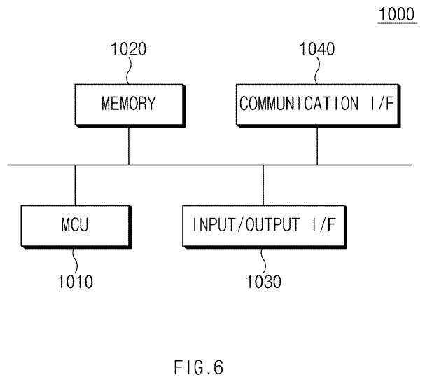

FIG. 6 is a block diagram showing a hardware configuration of a computing system for performing an operating method of a battery management apparatus, according to an embodiment disclosed herein.

Referring to FIG. 6, a computing system 3000 according to an embodiment disclosed herein may include a micro control unit (MCU) 1010, a memory 1020, an input/output I/F 1030, and a communication I/F 1040.

The MCU 1010 may be a processor that executes various programs stored in the memory 1020, processes various information including battery data, etc., through these programs, and performs functions of a processor (or a controller) included in the above-described battery management apparatus shown in FIG. 3.

The memory 1020 may store various programs for executing the functions of the battery management apparatus. The memory 1020 may store various information including battery data (voltage data, capacity data, etc.), differential capacity data, etc., and include an established database.

The memory 1020 may be provided in plural, depending on a need. The memory 1020 may be volatile memory or non-volatile memory. For the memory 1020 as the volatile memory, random access memory (RAM), dynamic RAM (DRAM), static RAM (SRAM), etc., may be used. For the memory 1020 as the nonvolatile memory, read only memory (ROM), programmable ROM (PROM), electrically alterable ROM (EAROM), erasable PROM (EPROM), electrically erasable PROM (EEPROM), flash memory, etc., may be used. The above-listed examples of the memory 1020 are merely examples and are not limited thereto.

The input/output I/F 1030 may provide an interface for transmitting and receiving data by connecting an input device (not shown) such as a keyboard, a mouse, a touch panel, etc., and an output device such as a display (not shown), etc., to the MCU 1010.

The communication I/F 1040, which is a component capable of transmitting and receiving various data to and from a server, may be various devices capable of supporting wired or wireless communication. For example, the battery management apparatus may transmit and receive various information including battery data, etc., from a separately provided external server through the communication I/F 1040.

As such, a computer program according to an embodiment disclosed herein may be recorded in the memory 1020 and processed by the MCU 1010, thus being implemented as a module that performs functions shown in FIG. 1.

Even though all components constituting an embodiment disclosed herein have been described above as being combined into one or operating in combination, the embodiments disclosed herein are not necessarily limited to the embodiments. That is, within the object scope of the embodiments disclosed herein, all the components may operate by being selectively combined into one or more.

Moreover, terms such as “include”, “constitute” or “have” described above may mean that the corresponding component may be inherent unless otherwise stated, and thus should be construed as further including other components rather than excluding other components. All terms including technical or scientific terms have the same meanings as those generally understood by those of ordinary skill in the art to which the embodiments disclosed herein pertain, unless defined otherwise. The terms used generally like terms defined in dictionaries should be interpreted as having meanings that are the same as the contextual meanings of the relevant technology and should not be interpreted as having ideal or excessively formal meanings unless they are clearly defined in the present document.

The above description is merely illustrative of the technical idea of the present disclosure, and various modifications and variations will be possible without departing from the essential characteristics of embodiments of the present disclosure by those of ordinary skill in the art to which the embodiments disclosed herein pertains. Therefore, the embodiments disclosed herein are intended for description rather than limitation of the technical spirit of the embodiments disclosed herein and the scope of the technical spirit of the present disclosure is not limited by these embodiments disclosed herein. The protection scope of the technical spirit disclosed herein should be interpreted by the following claims, and all technical spirits within the same range should be understood to be included in the range of the present document.

1. A battery management apparatus comprising:
a memory storing at least one instruction; and
a controller operatively connected to the memory, wherein the at least one instruction, when executed by the controller, causes the battery management apparatus, to:
obtain first charging/discharging data by performing a charging/discharging cycle on a first battery cell a first number of times;
input the first charging/discharging data to a two-dimensional (2D) convolutional neural network (CNN) trained on second charging/discharging data obtained by performing the charging/discharging cycle on at least one second battery cell a second number of times; and
predict a state of health (SOH) of the first battery cell based, at least in part, on result data output by the 2D CNN in response to the first charging/discharging data.

2. The battery management apparatus of claim 1, wherein the first number of times is less than the second number of times.

3. The battery management apparatus of claim 1, wherein the first charging/discharging data comprises one or more data sets including voltage data, current data, and temperature data corresponding to the first battery cell, and each of the one or more data sets corresponds to an instance of the charging/discharging cycle performed on the first battery cell.

4. The battery management apparatus of claim 3, wherein the at least one instruction, when executed by the controller, causes the battery management apparatus, to:
identify a quantity of data sets included in the first charging/discharging data for a designated time period;
determine that at least a portion of the first charging/discharging data is missing or incomplete in response to determining that the quantity of data sets is less than the first number of times;
determine a target number of additional cycle iterations by calculating a difference between the quantity of data sets and the first number of times; and
obtain third charging/discharging data by further performing the charging/discharging cycle for a number of iterations equal to the target number of additional cycle iterations.

5. The battery management apparatus of claim 4, wherein the at least one instruction, when executed by the controller, causes the battery management apparatus to:
input the third charging/discharging data to the 2D CNN;
generate the result data based, at least in part, on the third charging/discharging data; and
predict the SOH of the first battery cell based on the result data.

6. The battery management apparatus of claim 4, wherein the target number of additional cycle iterations is less than or equal to the first number of times.

7. The battery management apparatus of claim 1, wherein the at least one instruction, when executed by the controller, causes the battery management apparatus, to:
compare a prediction result generated by the 2D CNN based on the first charging/discharging data with an actual SOH of the first battery cell;
identify error data based on said comparison of the prediction result and the actual SOH, the error data comprising at least one of a root mean squared error (RMSE), a mean absolute error (MAE), a standard deviation (STD), or any combination thereof; and
utilize the error data to perform at least one of:
update a target number of times the charging/discharging cycle is executed to make a SOH prediction; or
further train the 2D CNN.

8. A battery management method comprising:
obtaining, by a controller, first charging/discharging data by performing a charging/discharging cycle on a first battery cell a first number of times;
inputting, by the controller, the first charging/discharging data to a two-dimensional (2D) convolutional neural network (CNN) trained on second charging/discharging data obtained by performing the charging/discharging cycle on at least one second battery cell a second number of times; and
predicting, by the controller, a state of health (SOH) of the first battery cell based, at least in part, on result data output by the 2D CNN in response to the first charging/discharging data.

9. The battery management method of claim 8, wherein the first number of times is less than the second number of times.

10. The battery management method of claim 8, further comprising:
identifying, by the controller, a quantity of data sets included in the first charging/discharging data for a designated time period;
determining, by the controller, that at least a portion of the first charging/discharging data is missing or incomplete in response to determining that the quantity of data sets is less than the first number of times;
determining a target number of additional cycle iterations by calculating a difference between the quantity of data sets and the first number of times; and
obtaining third charging/discharging data by further performing the charging/discharging cycle for a number of iterations equal to the target number of additional cycle iterations.

11. The battery management method of claim 10, further comprising:
inputting the third charging/discharging data to the 2D CNN;
generating the result data based, at least in part, on the third charging/discharging data; and
predicting the SOH of the first battery cell based on the result data.

12. The battery management method of claim 10, wherein the target number of additional cycle iterations is less than or equal to the first number of times.

13. The battery management method of claim 8, further comprising:
comparing a prediction result generated by the 2D CNN based on the first charging/discharging data with an actual SOH of the first battery cell;
identifying error data based on said comparison of the prediction result and the actual SOH, the error data comprising at least one of a root mean squared error (RMSE), a mean absolute error (MAE), a standard deviation (STD), or any combination thereof; and
utilizing the error data to perform at least one of:
updating a target number of times the charging/discharging cycle is executed to make a SOH prediction; or
further training the 2D CNN.
